(19) United States
(12) Patent Application Publication
(10) Pub. No.: US 2025/0140535 A1
(43) Pub. Date: May 1, 2025

(54) SUBSTRATE PROCESSING APPARATUS AND ELECTROSTATIC CHUCK

(71) Applicant: Tokyo Electron Limited, Tokyo (JP)

(72) Inventors: Takashi KANAZAWA, Miyagi (JP); Shin YAMAGUCHI, Miyagi (JP); Makoto KATO, Miyagi (JP); Ryoma MUTO, Miyagi (JP)

(73) Assignee: Tokyo Electron Limited, Tokyo (JP)

(21) Appl. No.: 19/010,578

(22) Filed: Jan. 6, 2025

Related U.S. Application Data
(63) Continuation of application No. PCT/JP2023/023647, filed on Jun. 26, 2023.
(60) Provisional application No. 63/358,913, filed on Jul. 7, 2022.

(51) Int. Cl. H01J 37/32

(52) U.S. Cl. CPC H01J 37/32724; H01J 2237/002; H01J 2237/2007

(57) ABSTRACT

A substrate processing apparatus includes a plasma processing chamber, a base arranged inside the plasma processing chamber, and an electrostatic chuck arranged on the base and having a substrate support surface and a ring support surface. The electrostatic chuck is configured to include a plurality of heat-transfer gas supply holes formed in the substrate support surface, an annular seal band formed on the substrate support surface around an outer periphery of the plurality of heat-transfer gas supply holes so as to surround the plurality of heat-transfer gas supply holes, and at least one first protrusion formed on the substrate support surface between a first heat-transfer gas supply hole closest to the seal band among the plurality of heat-transfer gas supply holes and the seal band.

### CROSS-REFERENCE TO RELATED APPLICATIONS

This application is a bypass continuation application of international application No. PCT/JP2023/023647 having an international filing date of Jun. 26, 2023 and designating the United States, the international application being based upon and claiming the benefit of priority from U.S. Patent Application No. 63/358,913, filed on Jul. 7, 2022, the entire contents of each are incorporated herein by reference.

### TECHNICAL FIELD

The present disclosure relates to a substrate processing apparatus and an electrostatic chuck.

### BACKGROUND

Patent Document 1 discloses that a plurality of holes for supplying and exhausting an ionized gas is provided in an electrostatic chuck. Further, Patent Document 1 discloses that three lift pin holes are formed in the electrostatic chuck.

### PRIOR ART DOCUMENT

### Patent Document

Patent Document 1: Japanese Laid-Open Patent Publication No. 2018-186179

### SUMMARY

A substrate processing apparatus according to one embodiment of the present disclosure includes a plasma processing chamber, a base arranged inside the plasma processing chamber, and an electrostatic chuck arranged on the base and having a substrate support surface and a ring support surface, wherein the electrostatic chuck is configured to include a plurality of heat-transfer gas supply holes formed in the substrate support surface, an annular seal band formed on the substrate support surface around an outer periphery of the plurality of heat-transfer gas supply holes so as to surround the plurality of heat-transfer gas supply holes, and at least one first protrusion formed on the substrate support surface between a first heat-transfer gas supply hole closest to the seal band among the plurality of heat-transfer gas supply holes and the seal band.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing an example of a plasma processing system in a first embodiment of the present disclosure.

FIG. 2 is a schematic sectional view showing an example of a configuration of a plasma processing apparatus according to the first embodiment.

FIG. 3 is a diagram showing an example of a substrate support surface of an electrostatic chuck according to the first embodiment.

FIG. 4 is a diagram showing an example of a cross section taken along line A-A in FIG. 3.

FIG. 5 is a diagram showing an example of a cross section near an annular groove.

FIG. 6 is a diagram showing an example of a substrate support surface near a heat-transfer gas supply hole.

FIG. 7 is a diagram showing an example of a substrate support surface of an electrostatic chuck according to Modification 1.

FIG. 8 is a diagram showing an example of a substrate support surface of an electrostatic chuck according to a second embodiment.

FIG. 9 is a diagram showing an example of a cross section taken along line A′-A′ in FIG. 8.

FIG. 10 is a diagram showing an example of a substrate support surface of an electrostatic chuck according to Modification 2.

### DETAILED DESCRIPTION

Hereinafter, embodiments of the disclosed substrate processing apparatus and electrostatic chuck will be described in detail with reference to the drawings. The disclosed technique is not limited to the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

For example, in an electrostatic chuck used in a substrate processing apparatus, it is known that a gas filling space to be filled with a heat-transfer gas is provided between a substrate support surface and a substrate in order to control a temperature of the substrate supported by the substrate support surface. The gas filling space is provided with protrusions for supporting the substrate. In addition, an annular seal band is provided around the outermost periphery of the substrate support surface to seal the gas filled in the gas filling space.

However, since the substrate support surface is provided with heat-transfer gas supply holes for supplying the heat-transfer gas to the gas filling space, positions of the protrusions and positions of the heat-transfer gas supply holes may interfere with each other, which makes it impossible to arrange the protrusions at preferred positions. In this case, since the protrusions are not arranged near the heat-transfer gas supply holes, the substrate is less likely to cool, and the temperature of the substrate near the heat-transfer gas supply holes is likely to rise more than other places. On the other hand, since the seal band is in annular contact with the substrate, the substrate is likely to cool, and the temperature of the substrate at the position where the substrate is in contact with the seal band is likely to fall more than other places. Therefore, for example, when the heat-transfer gas supply holes are located near the seal band, a temperature difference between the position where the substrate is in contact with the seal band and the position where the heat-transfer gas supply holes are located becomes large. For this reason, for example, the in-plane uniformity of the substrate temperature in plasma processing deteriorates, which is one of the causes of the deterioration of the quality and productivity of the substrate to be processed. Therefore, in order to improve the in-plane uniformity of the substrate temperature, the temperature difference on the substrate near the heat-transfer gas supply holes needs to be suppressed.

### First Embodiment

### [Configuration of Plasma Processing System]

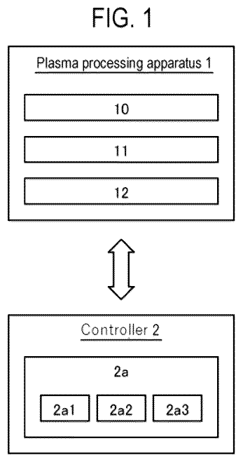

FIG. 1 is a diagram showing an example of a plasma processing system according to a first embodiment of the present disclosure. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas to the plasma processing space therethrough, and at least one gas exhaust port for exhausting the gas from the plasma processing space therethrough. The gas supply port is connected to a gas supplier 20 described later, and the gas exhaust port is connected to an exhaust system 40 described later. The substrate support 11 is arranged inside the plasma processing space and has a substrate support surface for supporting a substrate thereon.

The plasma generator 12 is configured to generate plasma from at least one processing gas supplied into the plasma processing space. The plasma formed in the plasma processing space may be capacitively-coupled plasma (CCP), inductively coupled plasma (ICP), electron-cyclotron-resonance plasma (ECR plasma), helicon wave plasma (HWP), or surface wave plasma (SWP). In addition, various types of plasma generators including an alternating current (AC) plasma generator and a direct current (DC) plasma generator may be used. In one embodiment, the AC signal (AC power) used in the AC plasma generator has a frequency in a range of 100 kHz to 10 GHz. Thus, the AC signal includes a radio frequency (RF) signal and a microwave signal. In one embodiment, the RF signal has a frequency in a range of 100 kHz to 150 MHz.

The controller 2 processes computer-executable instructions that cause the plasma processing apparatus 1 to execute various operations described in the present disclosure. The controller 2 may be configured to control individual elements of the plasma processing apparatus 1 to execute various operations described herein. In one embodiment, a part or the entirety of the controller 2 may be included in the plasma processing apparatus 1. The controller 2 may include a processor 2a1, a memory 2a2, and a communication interface 2a3. The controller 2 is implemented by, for example, a computer 2a. The processor 2al may be configured to perform various control operations by reading a program from the memory 2a2 and executing the read program. This program may be stored in the memory 2a2 in advance, or may be acquired via a medium when necessary. The acquired program is stored in the memory 2a2 and is read from the memory 2a2 and executed by the processor 2a1. The medium may be various storage media readable by the computer 2a, or may be a communication line connected to the communication interface 2a3. The processor 2al may be a CPU (Central Processing Unit). The memory 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network) or the like.

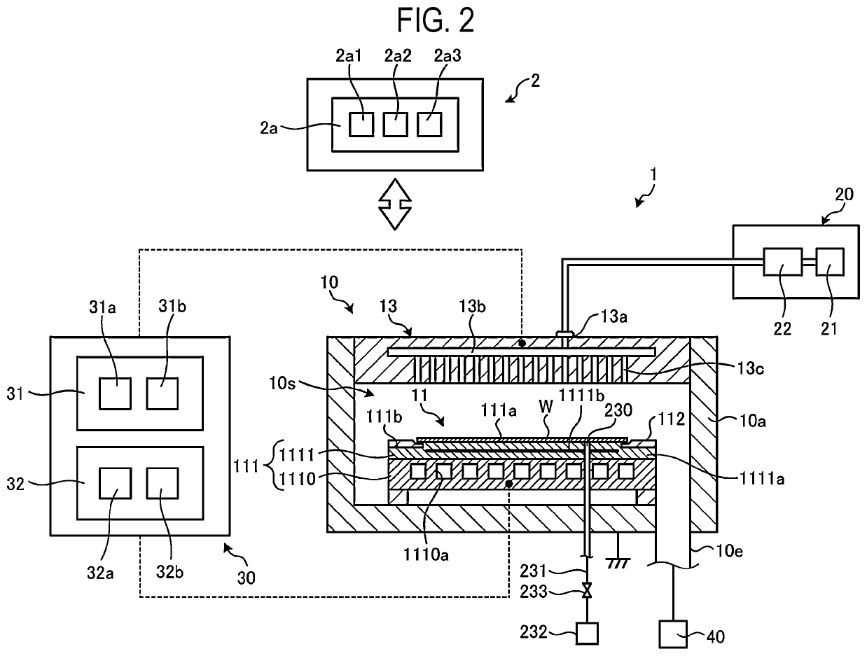

Next, a configuration example of a capacitively-coupled plasma processing apparatus will be described as an example of the plasma processing apparatus 1. FIG. 2 is a schematic sectional view showing an example of the configuration of the plasma processing apparatus according to the first embodiment.

A capacitively-coupled plasma processing apparatus 1 includes the plasma processing chamber 10, the gas supplier 20, a power supply 30, and the exhaust system 40. The plasma processing apparatus 1 also includes the substrate support 11 and a gas introducer. The gas introducer is configured to introduce at least one processing gas into the plasma processing chamber 10. The gas introducer includes a showerhead 13. The substrate support 11 is arranged inside the plasma processing chamber 10. The showerhead 13 is arranged above the substrate support 11. In one embodiment, the showerhead 13 constitutes at least a portion of a ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from a housing of the plasma processing chamber 10.

The substrate support 11 includes a main body 111 and a ring assembly 112. The main body 111 has a central region 111a for supporting a substrate W thereon and an annular region 111b for supporting the ring assembly 112 thereon. A wafer is an example of the substrate W. The annular region 111b of the main body 111 surrounds the central region 111a of the main body 111 in a plan view. The substrate W is arranged on the central region 111a of the main body 111, and the ring assembly 112 is arranged on the annular region 111b of the main body 111 so as to surround the substrate W on the central region 111a of the main body 111. Therefore, in the following description, the central region 111a may be referred to as a substrate support surface 111a for supporting the substrate W thereon, and the annular region 111b may be referred to as a ring support surface 111b for supporting the ring assembly 112 thereon.

In one embodiment, the main body 111 includes a base 1110 and an electrostatic chuck 1111. The base 1110 includes a conductive member. The conductive member of the base 1110 may function as a lower electrode. The electrostatic chuck 1111 is arranged on the base 1110. The electrostatic chuck 1111 includes a ceramic member 1111a and an electrostatic electrode 1111b arranged inside the ceramic member 1111a. The ceramic member 1111a has a central region 111a. In one embodiment, the ceramic member 1111a also has an annular region 111b. Other members surrounding the electrostatic chuck 1111, such as an annular electrostatic chuck, an annular insulating member and the like, may have the annular region 111b. In this case, the ring assembly 112 may be arranged on the annular electrostatic chuck or the annular insulating member, or may be arranged on both the electrostatic chuck 1111 and the annular insulating member. Further, at least one RF/DC electrode coupled to an RF power supply 31 and/or a DC power supply 32 described later may be arranged inside the ceramic member 1111a. In this case, the at least one RF/DC electrode functions as a lower electrode. When a bias RF signal and/or a DC signal described later is supplied to the at least one RF/DC electrode, the RF/DC electrode is also called a bias electrode. The conductive member of the base 1110 and the at least one RF/DC electrode may function as multiple lower electrodes. In addition, the electrostatic electrode 1111b may function as a lower electrode. Thus, the substrate support 11 includes at least one lower electrode.

The ring assembly 112 includes one or more annular members. In one embodiment, the one or more annular members include one or more edge rings and at least one cover ring. The edge rings are formed of a conductive or insulating material, and the cover ring is formed of an insulating material.

Further, the substrate support 11 may include a temperature adjustment module configured to adjust a temperature of at least one of the electrostatic chuck 1111, the ring assembly 112, and the substrate to a target temperature. The temperature adjustment module may include a heater, a heat transfer medium, a flow path 1110a, or a combination thereof. A heat transfer fluid such as brine or a gas flows through the flow path 1110a. In one embodiment, the flow path 1110a is formed in the base 1110, and one or more heaters are arranged inside the ceramic member 1111a of the electrostatic chuck 1111. Further, the substrate support 11 includes a heat-transfer gas supplier 232 configured to supply a heat-transfer gas to a gap (gas filling space) between a back surface of the substrate W and the substrate support surface 111a. The substrate support surface 111a is provided with a plurality of heat-transfer gas supply holes 230, which will be described later. Each of the heat-transfer gas supply holes 230 is connected to each of heat-transfer gas supply paths 231. Each of the heat-transfer gas supply paths 231 is connected to a heat-transfer gas supplier 232 via a control valve 233. The heat-transfer gas (backside gas) may be, for example, a helium gas.

The showerhead 13 is configured to introduce at least one processing gas from the gas supplier 20 into the plasma processing space 10s. The showerhead 13 has at least one gas supply port 13a, at least one gas diffusion chamber 13b, and a plurality of gas introduction holes 13c. The processing gas supplied to the gas supply port 13a passes through the gas diffusion chamber 13b and is introduced into the plasma processing space 10s from the plurality of gas introduction holes 13c. Further, the showerhead 13 includes at least one upper electrode. In addition to the showerhead 13, the gas introducer may include one or more side gas injectors (SGIs) attached to one or more openings formed in the sidewall 10a.

The gas supplier 20 may include at least one gas source 21 and at least one flow rate controller 22. In one embodiment, the gas supplier 20 is configured to supply at least one processing gas from each gas source 21 via each flow rate controller 22 to the showerhead 13. Each flow rate controller 22 may include, for example, a mass flow controller or a pressure-controlled flow rate controller. Further, the gas supplier 20 may include at least one flow rate modulation device for modulating or pulsing a flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is generated from at least one processing gas supplied to the plasma processing space 10s. Thus, the RF power supply 31 may function as at least a portion of the plasma generator 12. In addition, by supplying a bias RF signal to the at least one lower electrode, a bias potential is generated on the substrate W, and ion components in the formed plasma may be attracted to the substrate W.

In one embodiment, the RF power supply 31 includes a first RF generator 31a and a second RF generator 31b. The first RF generator 31a is coupled to the at least one lower electrode and/or the at least one upper electrode via at least one impedance matching circuit, and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The plurality of source RF signals thus generated is supplied to the at least one lower electrode and/or the at least one upper electrode.

The second RF generator 31b is coupled to the at least one lower electrode via at least one impedance matching circuit and is configured to generate a bias RF signal (bias RF power). A frequency of the bias RF signal may be the same as or different from the frequency of the source RF signal. In one embodiment, the bias RF signal has a lower frequency than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The plurality of bias RF signals thus generated is supplied to the at least one lower electrode. Further, in various embodiments, at least one of the source RF signal and the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to the at least one lower electrode and is configured to generate a first DC signal. The first DC signal thus generated is applied to the at least one lower electrode. In one embodiment, the second DC generator 32b is connected to the at least one upper electrode and is configured to generate a second DC signal. The second DC signal thus generated is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular, trapezoidal, or triangular pulse waveform, or a combination thereof. In one embodiment, a waveform generator for generating the sequence of voltage pulses from the DC signal is connected between the first DC generator 32a and the at least one lower electrode. Thus, the first DC generator 32a and the waveform generator constitute a voltage pulse generator. When the second DC generator 32b and the waveform generator constitute the voltage pulse generator, the voltage pulse generator is connected to the at least one upper electrode. The voltage pulses may have a positive polarity or a negative polarity. Further, the sequence of voltage pulses may include one or more positive polarity voltage pulses and one or more negative polarity voltage pulses in one period. The first DC generator 32a and the second DC generator 32b may be provided in addition to the RF power supply 31, or the first DC generator 32a may be provided in place of the second RF generator 31b.

The exhaust system 40 may be connected to, for example, the gas exhaust port 10e provided at the bottom of the plasma processing chamber 10. The exhaust system 40 may include a pressure regulation valve and a vacuum pump. An internal pressure of the plasma processing space 10s is regulated by the pressure regulation valve. The vacuum pump may include a turbo-molecular pump, a dry pump, or a combination thereof.

### [Details of Electrostatic Chuck 1111]

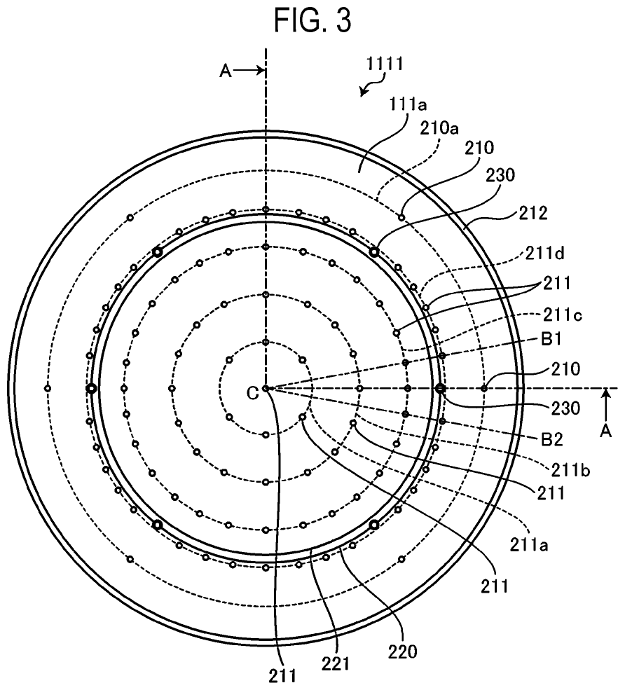

FIG. 3 is a diagram showing an example of the substrate support surface of the electrostatic chuck according to the first embodiment. As shown in FIG. 3, the substrate support surface 111a of the electrostatic chuck 1111 is provided with a plurality of protrusions 210 and 211, a seal band 212, and the plurality of heat-transfer gas supply holes 230. In FIG. 3, the ring support surface 111b is omitted. The protrusions 210 and 211 are formed so that the top portions thereof come into contact with the substrate W on the substrate support surface 111a, and are configured to support the substrate W. The seal band 212 is formed in a ring shape on the outermost periphery of the substrate support surface 111a, and is configured to support the substrate W by coming into contact with the outer periphery of the substrate W. In other words, the substrate W is supported by the plurality of protrusions 210 and 211 and the seal band 212. The outermost periphery of the substrate W protrudes outward beyond the seal band 212. The seal band 212 is an annular seal band formed outside the heat-transfer gas supply holes 230 so as to surround the heat-transfer gas supply holes 230.

The heat-transfer gas supply holes 230 are holes for supplying the heat-transfer gas supplied from the heat-transfer gas supplier 232 to the gap (gas filling space) between the back surface of the substrate W and the substrate support surface 111a. The heat-transfer gas supply holes 230 are formed along an annular groove 220 formed on the substrate support surface 111a in, for example, a point-symmetrical relationship with the center of the substrate support surface 111a in a plan view. Similarly, an annular groove 221 is formed on the inner periphery side of the groove 220. The heat-transfer gas supply holes 230 are an example of first heat-transfer gas supply holes.

The protrusions 210 are formed between the heat-transfer gas supply holes 230 and the seal band 212. The protrusions 210 are formed, for example, on extension lines of the lines connecting the center of the substrate support surface 111a and the heat-transfer gas supply holes 230 and on a circumference 210a whose axis is the center of the substrate support surface 111a. In this case, the circumference 210a is concentric with the groove 220. The protrusions 210 are an example of first protrusions.

On the substrate support surface 111a, the protrusions 211 are formed at the center of the substrate support surface 111a and on the circumferences 211a to 211d that are concentric with the groove 220 in which the heat-transfer gas supply holes 230 are formed. In the example of FIG. 3, the protrusions 211 are formed sequentially from the center side of the substrate support surface 111a as follows: one protrusion is formed at the center of the substrate support surface 111a, 6 protrusions are formed on the circumference 211a, 16 protrusions are formed on the circumference 211b, 28 protrusions are formed on the circumference 211c, and 34 protrusions are formed on the circumference 211d. The protrusions 211 are an example of second protrusions, and the shape and number of the protrusions 211 are optional. The protrusions 210 and 211 are also called dots. The protrusions 211 are preferably formed at equal intervals in the circumferential direction of the substrate support surface 111a. However, the intervals at which the protrusions 211 are formed may be adjusted to improve in-plane uniformity.

Now, the protrusions 211 on the circumference 211d will be considered. As shown in FIG. 3, the groove 220 in which the heat-transfer gas supply holes 230 are formed is located adjacent to the circumference 211d on the inner circumferential side of the circumference 211d. On the circumference 211d, it is difficult to form the protrusions 211 at positions interfere with the positions of the heat-transfer gas supply holes 230. Therefore, the protrusions 210 are formed within a range between extension lines obtained by extending lines that connect the two protrusions 211 located ahead and behind the heat-transfer gas supply holes 230 in the circumferential direction on the circumference 211d closest to the groove 220 among the circumferences 211a to 211d and the center of the substrate support surface 111a toward the seal band 212. Taking the 3 o'clock direction in FIG. 3 as an example, a range surrounded by the seal band 212 and the line C-B1 and line C-B2 with the center of the substrate support surface 111a as point C is a region where the protrusions 210 are formed. For example, each protrusion 210 is formed at the intersection of the circumference 210a and the extension line of the line connecting the point C and the heat-transfer gas supply hole 230. An angle between the line C-B1 and the line C-B2 may be set to, for example, 30 degrees or less.

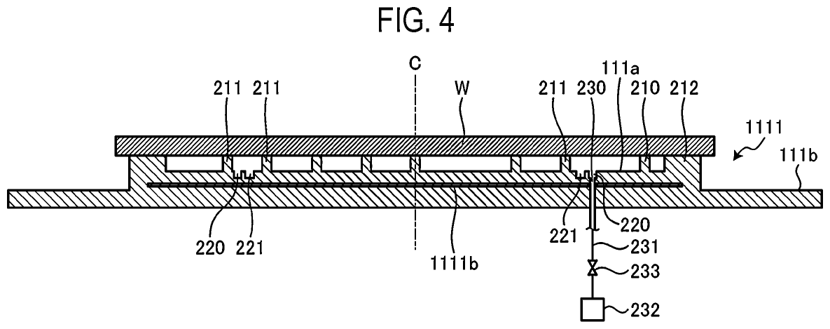

FIG. 4 is a diagram showing an example of a cross section taken along line A-A in FIG. 3. As shown in FIG. 4, the substrate W is supported on the substrate support surface 111a by the protrusions 210 and 211 and the seal band 212. There is the gap between the back surface of the substrate W and the substrate support surface 111a. The grooves 220 and 221 are depressed from the substrate support surface 111a and have a rectangular shape in a cross-sectional view. The ring assembly 112 on the ring support surface 111b is omitted. The heat-transfer gas supply holes 230 are formed at the bottom of the groove 220, and are connected to the heat-transfer gas supplier 232 via the heat-transfer gas supply path 231 and the control valve 233. The heat-transfer gas supplied from the heat-transfer gas supply holes 230 fill the grooves 220, 221 and the gap between the back surface of the substrate W and the substrate support surface 111a. In FIG. 4, porous members 234 (to be described later) inside the heat-transfer gas supply holes 230 are omitted.

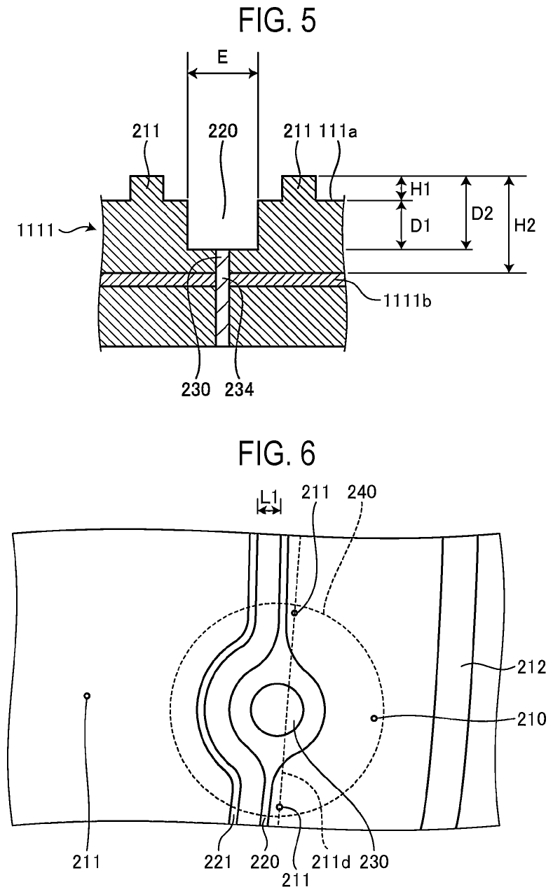

FIG. 5 is a diagram showing an example of a cross section near the annular groove. In FIG. 5, the groove 221 is omitted for the sake of simplification in illustration. As shown in FIG. 5, a depth D1 of the annular groove 220 (depth from the substrate support surface 111a to the bottom of the groove 220) is equal to or greater than a height H1 of the protrusion 211 (height from the substrate support surface 111a to an upper surface of the protrusion 211). In addition, a depth D2 of the groove 220 (depth from the upper surface of the protrusion 211 to the bottom of the groove 220) is equal to or greater than twice the height H1 of the protrusion 211. For example, when the height H1 of the protrusion 211 is 5 μm to 20 μm, the depth D2 of the groove 220 is 10 μm to 40 μm. Upper limit values of the depths D1 and D2 of the groove 220 are not particularly limited. For example, the groove 220 may extend vertically downward to a position slightly above the upper surface of the electrostatic electrode 1111b with the bottom thereof not reaching the electrostatic electrode 1111b a. In addition, for example, the depth D1 of the groove 220 may be equal to or less than half a distance H2 from the upper surface of the protrusion 211 to the upper surface of the electrostatic electrode 1111b. A width E of the groove 220 is not particularly limited, but may be, for example, 0.3 mm to 10 mm. In addition, each porous member 234, which is a porous body for suppressing abnormal discharge, is arranged inside the heat-transfer gas supply hole 230. The porous member 234 allows the heat-transfer gas to pass through the interior thereof. The porous member 234 does not have to be arranged inside the heat-transfer gas supply hole 230, and may be arranged inside a portion of the interior of the heat-transfer gas supply hole 230.

FIG. 6 is a diagram showing an example of the vicinity of the heat-transfer gas supply hole on the substrate support surface. As shown in FIG. 6, in the vicinity of the heat-transfer gas supply hole 230, the groove 220 is widened so as to surround the heat-transfer gas supply hole 230. In addition, the groove 221 is detouring toward the center side of the substrate support surface 111a so that a distance between the groove 220, which is widened in the vicinity of the heat-transfer gas supply hole 230, and the groove 221 is substantially the same as that at a position not in the vicinity of the heat-transfer gas supply hole 230. A groove distance LI between the groove 220 and the groove 221 at the position not in the vicinity of the heat-transfer gas supply hole 230 is, for example, 1 mm to 10 mm. In a region 240 representing an example of a predetermined range centered on the heat-transfer gas supply hole 230, the protrusion 210 is formed between the heat-transfer gas supply hole 230 and the seal band 212. In other words, the protrusion 210 is formed in the region 240 so as to complement a portion where the gap between the protrusions 211 on the circumference 211d becomes wider due to the heat-transfer gas supply hole 230.

A range in which the protrusion 210 is formed is not limited to the region 240. That is, as shown in FIG. 3, on the circumference 211d closest to the groove 220, the protrusion 210 may be formed within a range between the extension lines obtained by extending the lines that connect the two protrusions 211 located ahead and behind the heat-transfer gas supply hole 230 and the center of the substrate support surface 111a toward the seal band 212. In FIG. 6, two protrusions 211 on the circumference 211d located within the region 240 correspond to two protrusions located ahead and behind the heat-transfer gas supply hole 230 in the circumferential direction of the substrate support surface 111a. In addition, the groove 220 is an example of a first circumference, and the circumference 211d is an example of a second circumference.

As described above, since the protrusion 210 is formed between the heat-transfer gas supply holes 230 and the seal band 212 so as to complement the portion where the gap between the protrusions 211 in the vicinity of the heat-transfer gas supply hole 230 becomes wider, it is possible to suppress the temperature difference on the substrate W in the vicinity of the heat-transfer gas supply holes 230. That is, in the first embodiment, it is possible to suppress the occurrence of temperature fluctuation around the heat-transfer gas supply holes 230. Therefore, in the first embodiment, it is possible to improve the in-plane uniformity of the substrate temperature, which improves the in-plane uniformity of the processing on the substrate W to be processed.

In the first embodiment, each heat-transfer gas supply hole 230 is provided at the bottom of the groove 220 on the same circumference. However, the heat-transfer gas supply holes 230 may be additionally provided on the substrate support surface 111a at the positions closer to the center than the groove 220. In this case, the protrusions 210 are formed between the heat-transfer gas supply holes 230 closest to the seal band 212 and the seal band 212. However, the protrusions 210 may be formed near the additionally-provided heat-transfer gas supply holes 230. The additionally-provided heat-transfer gas supply holes 230 may be formed at the bottom of the groove corresponding to the groove 220, or a plurality of annular grooves corresponding to the groove 221 may be formed in the radial direction of the substrate support surface 111a. Further, the grooves 221 may be formed, for example, on the inner and outer circumferential sides of the groove 220 in the radial direction of the substrate support surface 111a. In other words, three grooves such as the groove 221, the groove 220, and the groove 221, may be formed in the named order from the inner periphery side in the radial direction of the substrate support surface 111a.

### (Modification 1)

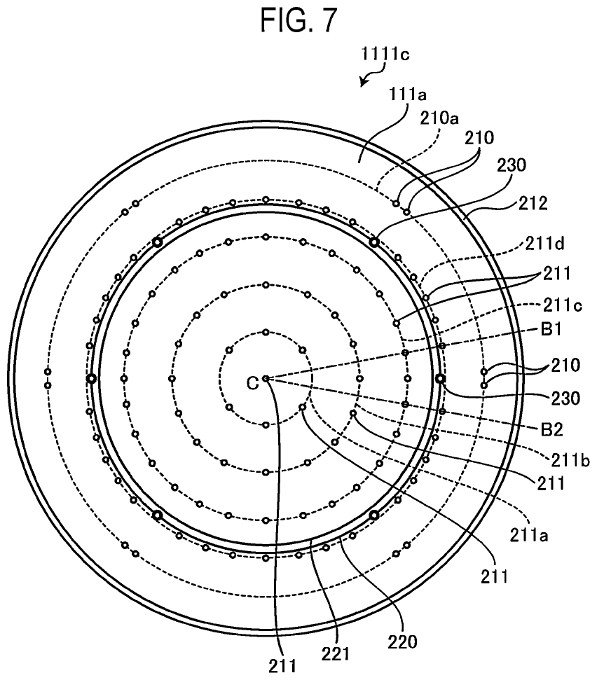

Next, Modification 1 of the first embodiment will be described with reference to FIG. 7. FIG. 7 is a diagram showing an example of a substrate support surface of an electrostatic chuck according to Modification 1. A plasma processing apparatus 1 according to Modification 1 includes an electrostatic chuck 1111c shown in FIG. 7 instead of the electrostatic chuck 1111. The plasma processing apparatus 1 according to Modification 1 is similar to the above-described first embodiment except for a configuration of the electrostatic chuck 1111c. Therefore, descriptions of the overlapping configuration and operation will be omitted. Further, in FIG. 7, the ring support surface 111b is omitted.

As shown in FIG. 7, similar to the electrostatic chuck 1111, a plurality of protrusions 210 and 211, a seal band 212, and a plurality of heat-transfer gas supply holes 230 are formed on the substrate support surface 111a of the electrostatic chuck 1111c. The electrostatic chuck 1111c is different from the electrostatic chuck 1111 in terms of the number of protrusions 210 formed on the circumference 210a. The protrusions 210 are formed, for example, on the circumference 210a whose axis is the center of the substrate support surface 111a, so that one protrusion 210 is formed on each of the left and right sides of an extension line of the line that connects the center of the substrate support surface 111a and the heat-transfer gas supply hole 230, so as to correspond to each heat-transfer gas supply hole 230. In other words, two protrusions 210 are formed between the heat-transfer gas supply hole 230 and the seal band 212 for each heat-transfer gas supply hole 230. Taking the 3 o'clock direction in FIG. 7 as an example, a range surrounded by lines C-B1 and C-B2 with point C at the center of the substrate support surface 111a and the seal band 212 is a region where two protrusions 210 are formed. Thus, the electrostatic chuck 1111c may further suppress the temperature difference on the substrate W in the vicinity of the heat-transfer gas supply hole 230. For one heat-transfer gas supply hole 230, three or more protrusions 210 may be formed between the heat-transfer gas supply hole 230 and the seal band 212.

### Second Embodiment

In the above-described first embodiment, the seal band 212 has been described to be formed in the ring shape on the outermost periphery of the substrate support surface 111a. However, a seal band may be further provided on the inner periphery side of the substrate support surface 111a. An embodiment in this case will be described as a second embodiment. A plasma processing apparatus 1 according to a second embodiment is similar to the above-described first embodiment except for a configuration of the electrostatic chuck 1111. Therefore, descriptions of the overlapping configuration and operation will be omitted.

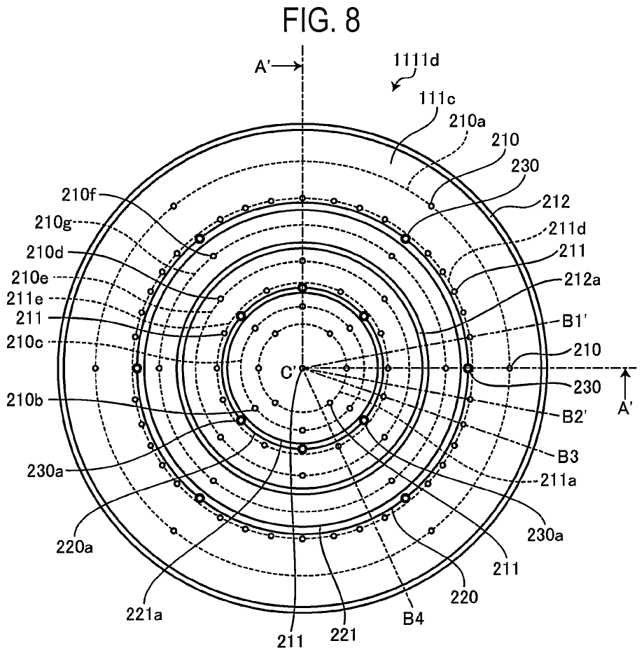

FIG. 8 is a diagram showing an example of a substrate support surface of an electrostatic chuck according to the second embodiment. The plasma processing apparatus 1 according to the second embodiment includes an electrostatic chuck 1111d shown in FIG. 8 instead of the electrostatic chuck 1111. A plurality of protrusions 210, 210b, 210d, 210f and 211, seal bands 212 and 212a, and a plurality of heat-transfer gas supply holes 230 and 230a are formed on the substrate support surface 111c of the electrostatic chuck 1111d. That is, compared to the substrate support surface 111a of the electrostatic chuck 1111, a plurality of protrusions 210b, 210d and 210f, a seal band 212a, and a plurality of heat-transfer gas supply holes 230a are additionally provided on the substrate support surface 111c of the electrostatic chuck 1111d. The ring support surface 111b is omitted in FIG. 8.

In the radial direction of the substrate support surface 111c, the seal band 212a is formed between the groove 220 in which the heat-transfer gas supply holes 230 are provided and the annular groove 220a in which the heat-transfer gas supply holes 230a are provided. The seal band 212a supports the substrate W by coming into contact with the vicinity of the center of the substrate W in the radial direction. A region in which the seal band 212a comes into contact with the substrate W is not limited to the vicinity of the center of the substrate W in the radial direction. The seal band 212a is an annular seal band formed on the outer periphery of the heat-transfer gas supply holes 230a so as to surround the heat-transfer gas supply holes 230a. That is, in the electrostatic chuck 1111d, pressures of the heat-transfer gas applied to the heat-transfer gas supply holes 230 and 230a may be adjusted, respectively, so that the substrate support surface 111c is divided into a plurality of regions using, for example, the seal band 212a as a boundary.

The heat-transfer gas supply holes 230a are holes for supplying the heat-transfer gas supplied from the heat-transfer gas supplier 232 to the gap between the back surface of the substrate W and the substrate support surface 111c. The heat-transfer gas supply holes 230a are formed along the annular groove 220a formed on the substrate support surface 111c in, for example, a point-symmetrical relationship with the center of the substrate support surface 111c in a plan view. The heat-transfer gas supply holes 230a are formed on the inner periphery side of the substrate support surface 111c relative to the seal band 212a. Further, an annular groove 221a is formed on the inner periphery side of the groove 220a. The heat-transfer gas supply holes 230a are an example of second heat-transfer gas supply holes closest to the seal band 212a.

The protrusions 210b, 210d and 210f are respectively formed on circumferences 210c, 210e and 210g, which are concentric with the groove 220, in the named order from the inner periphery side. In this case, the circumference 211a, the circumference 210c, the groove 221a, the groove 220a, the circumference 211e, the circumference 210e, the seal band 212a, the circumference 210g, the groove 221, the groove 220, the circumference 211d, the circumference 210a, and the seal band 212 are arranged sequentially from the center of the substrate support surface 111c to the outer periphery side thereof.

The protrusions 210b and 210d are formed, for example, on the circumferences 210c and 210e and on the lines connecting the center of the substrate support surface 111c and the heat-transfer gas supply holes 230a and the extension lines thereof. The protrusions 210f are formed, for example, on the circumference 210g and on the lines connecting the center of the substrate support surface 111c and the heat-transfer gas supply holes 230. That is, the protrusions 210b and 210f of the second embodiment are formed on the inner periphery side of the heat-transfer gas supply holes 230a and 230, respectively. Further, the protrusions 210d are formed on the outer periphery side of the heat-transfer gas supply holes 230a, respectively. The protrusions 210f are formed on the lines connecting the center of the substrate support surface 111c and the heat-transfer gas supply holes 230, just like the protrusions 210. Further, the protrusion 210d is an example of at least one third protrusion formed between the second heat-transfer gas supply hole (heat-transfer gas supply hole 230a) and the seal band 212a.

As on the circumference 211d, the protrusions 211 are formed on the circumferences 211a and 211e, which are concentric with the groove 220. In the example of FIG. 8, the protrusions 211 are formed sequentially from the center side of the substrate support surface 111c as follows: one protrusion is formed at the center of the substrate support surface 111a, 6 protrusions are formed on the circumference 211a, 10 protrusions are formed on the circumference 211e, and 34 protrusions are formed on the circumference 211d.

Now, the protrusions 211 on the circumference 211e will be considered. On the inner circumferential side of the circumference 211e, the groove 220a in which the heat-transfer gas supply holes 230a are formed is located adjacent to the circumference 211e. On the circumference 211e, as on the circumference 211d, the protrusions 211 are less likely to be formed at the positions that interfere with the positions of the heat-transfer gas supply holes 230a. Therefore, on the circumference 211e closest to the groove 220a among the circumferences on which the protrusions 211 are formed, the protrusions 210b and 210d are formed within a range between extension lines obtained by extending lines that connect the two protrusions 211 located ahead and behind the heat-transfer gas supply holes 230a in the circumferential direction and the center of the substrate support surface 111c toward the seal band 212.

Taking the 3 o'clock direction in FIG. 8 as an example, a range surrounded by lines C′-B1′ and C′-B2′ with the center of the substrate support surface 111c as point C′ and the seal bands 212 and 212a is a region where the protrusions 210 and 210f are formed. For example, the protrusions 210 and 210f are formed at the intersections of the extension lines of the lines connecting the point C′ and the heat-transfer gas supply holes 230 with the circumferences 210a and 210g. Taking the 4 o'clock to 5 o'clock directions in FIG. 8 as an example, a range surrounded by lines C′-B3 and C′-B4 with the center of the substrate support surface 111c as point C′ and the seal bands 212a is a region where the protrusions 210b and 210d are formed. For example, the protrusions 210b and 210d are formed at the intersections of the extension lines of the lines connecting the point C′ and the heat-transfer gas supply holes 230a with the circumferences 210c and 210e. An angle between the lines C′-B1′ and C′-B2′ may be set to, for example, 30 degrees or less, and an angle between the lines C′-B3 and C′-B4 may be set to, for example, 60 degrees or less.

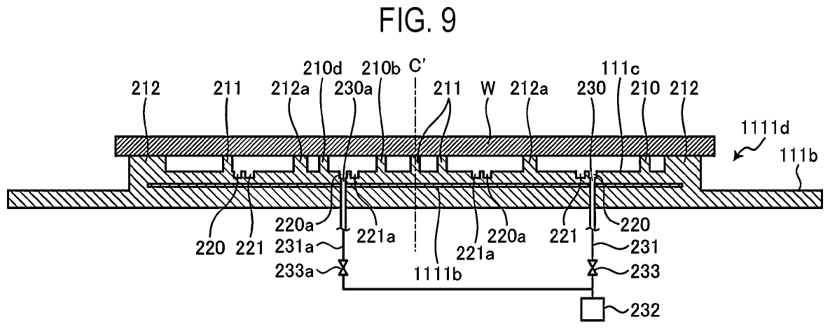

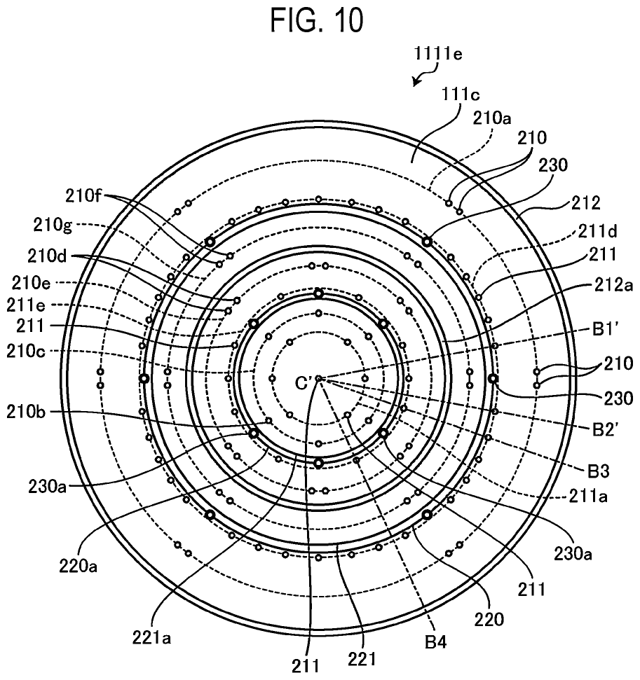

FIG. 9 is a diagram showing an example of a cross section taken along line A′-A′ in FIG. 8. As shown in FIG. 9, the substrate W is supported on the substrate support surface 111c by the protrusions 210, 210b, 210d, 210f and 211, and the seal bands 212 and 212a. A gap is formed between the back surface of the substrate W and the substrate support surface 111c. The ring assembly 112 on the ring support surface 111b is omitted. For the sake of convenience in illustration of the cross section, the protrusions 210f are not shown in FIG. 9. The grooves 220, 220a, 221 and 221a are depressed from the substrate support surface 111c and have a rectangular shape in a cross-sectional view. The heat-transfer gas supply holes 230 and 230a are formed at the bottoms of the grooves 220 and 220a, respectively, and are connected to the heat-transfer gas supplier 232 via the heat-transfer gas supply paths 231 and 231a and control valves 233 and 233a, respectively. The heat-transfer gas supplier 232 may be provided independently for each of the heat-transfer gas supply paths 231 and 231a. The heat-transfer gas supplied from the heat-transfer gas supply holes 230 and 230a fills the grooves 220, 220a, 221 and 221a and the gap between the back surface of the substrate W and the substrate support surface 111c. The porous members 234 inside the heat-transfer gas supply holes 230 and 230a are omitted in FIG. 9.

As described above, the protrusions 210 and 210d are formed between the heat-transfer gas supply holes 230 and 230a and the seal bands 212 and 212a in the vicinity of the heat-transfer gas supply holes 230 and 230a, respectively. In addition, the protrusions 210b and 210f are formed on the inner periphery side of the heat-transfer gas supply holes 230 and 230a, respectively. Therefore, even if the plurality of seal bands are formed on the substrate support surface 111c, it is possible to suppress the temperature difference on the substrate W in the vicinity of the heat-transfer gas supply holes 230 and 230a.

In the second embodiment, the heat-transfer gas supply holes 230 has been described to be provided at the bottom of the groove 220 on the same circumference. However, the heat-transfer gas supply holes 230 may be additionally provided between the groove 220 and the seal band 212a on the substrate support surface 111c. In this case, the protrusions 210 are formed at least between the heat-transfer gas supply holes 230 closest to the seal band 212 and the seal band 212. Similarly, the heat-transfer gas supply holes 230a are provided at the bottom of the groove 220a on the same circumference. However, the heat-transfer gas supply holes 230a may be additionally provided on the center side of the groove 220a on the substrate support surface 111c. In this case, the protrusions 210d are formed at least between the heat-transfer gas supply holes 230a closest to the seal band 212a and the seal band 212a. As in the above-mentioned substrate support surface 111c, not only the protrusions 211 but also the protrusions 210f and 210b may be formed on the center side of the grooves 220 and 220a in which the heat-transfer gas supply holes 230 and 230a are formed. Further, in the radial direction of the substrate support surface 111c, for example, the grooves 221 and 221a may be formed on the inner and outer periphery sides of the grooves 220 and 220a, respectively. That is, sequentially from the inner periphery side in the radial direction of the substrate support surface 111c, three grooves such as the groove 221a, the groove 220a, and the groove 221a, may be formed in the vicinity of the groove 220a, and three grooves such as the groove 221, the groove 220, and the groove 221, may be formed in the vicinity of the groove 220.

### (Modification 2)

Next, Modification 2 of the second embodiment will be described with reference to FIG. 10. FIG. 10 is a diagram showing an example of a substrate support surface of an electrostatic chuck according to Modification 2. A plasma processing apparatus 1 according to Modification 2 includes an electrostatic chuck 1111e shown in FIG. 10 instead of the electrostatic chuck 1111d. The plasma processing apparatus 1 according to Modification 2 is similar to the above-described second embodiment except for a configuration of the electrostatic chuck 1111e.

Therefore, descriptions of the overlapping configuration and operation will be omitted. The ring support surface 111b is omitted in FIG. 10.

As shown in FIG. 10, just like the electrostatic chuck 1111d, the electrostatic chuck 1111e has a substrate support surface 111c provided with a plurality of protrusions 210, 210b, 210d, 210f and 211, seal bands 212 and 212a, and a plurality of heat-transfer gas supply holes 230 and 230a. The electrostatic chuck 1111e is different from the electrostatic chuck 1111d in terms of the number of protrusions 210, 210d and 210f formed on the circumferences 210a, 210e and 210g.

The protrusions 210 are formed, for example, on the circumference 210a whose axis is the center of the substrate support surface 111c such that one protrusion is formed each of right and left sides of the extension line of the line connecting the center of the substrate support surface 111c and the heat-transfer gas supply hole 230, so as to correspond to each of the heat-transfer gas supply holes 230. The protrusions 210d are formed, for example, on the circumference 210e whose axis is the center of the substrate support surface 111c such that one protrusion is formed each of right and left sides of the extension line of the line connecting the center of the substrate support surface 111c and the heat-transfer gas supply hole 230a, so as to correspond to each of the heat-transfer gas supply holes 230a. The protrusions 210f are formed, for example, on the circumference 210g whose axis is the center of the substrate support surface 111c such that one protrusion is formed each of right and left sides of the line connecting the center of the substrate support surface 111c and the heat-transfer gas supply hole 230, so as to correspond to each of the heat-transfer gas supply holes 230.

That is, for each heat-transfer gas supply hole 230, two protrusions 210 are formed between the heat-transfer gas supply hole 230 and the seal band 212, and two protrusions 210f are formed between the heat-transfer gas supply hole 230 and the seal band 212a. For each heat-transfer gas supply hole 230, three or more protrusions 210 may be formed between the heat-transfer gas supply hole 230 and the seal band 212. For each heat-transfer gas supply hole 230, three or more protrusions 210f may be formed between the heat-transfer gas supply hole 230 and the seal band 212a. For each heat-transfer gas supply hole 230a, two protrusions 210d are formed between the heat-transfer gas supply hole 230a and the seal band 212a, and one protrusion 210b is formed between the heat-transfer gas supply hole 230a and the center of the substrate support surface 111c. The protrusions 210d may be formed such that three or more protrusions 210d are formed between the heat-transfer gas supply hole 230a and the seal band 212a for each heat-transfer gas supply hole 230a. In addition, the protrusions 210b may be formed such that two or more protrusions 210b are formed between the heat-transfer gas supply hole 230a and the center of the substrate support surface 111c for each heat-transfer gas supply hole 230a.

That is, taking the 3 o'clock direction in FIG. 10 as an example, a range surrounded by lines C′-B1′ and C′-B2′ with the center of the substrate support surface 111c at point C′ and the seal bands 212 and 212a is a region where two protrusions 210 and 210f are formed. Taking the 4 o'clock to 5 o'clock direction in FIG. 10 as an example, a range surrounded by lines C′-B3 and C′-B4 with the center of the substrate support surface 111c at point C′ and the seal band 212a is a region where one protrusion 210b and two protrusions 210d are formed. As a result, even if the substrate support surface 111c is divided into a plurality of regions by the seal band 212a, the electrostatic chuck 1111e may further suppress the temperature difference on the substrate W in the vicinity of the heat-transfer gas supply holes 230 and 230a.

According to each embodiment described above, the substrate processing apparatus (the plasma processing apparatus 1) includes the plasma processing chamber 10, the base (the substrate support 11) arranged inside the plasma processing chamber 10, and the electrostatic chuck (the electrostatic chuck 1111 or 1111c to 1111e) arranged on the base and having the substrate support surface (the substrate support surface 111a or 111c) and the ring support surface 111b. The electrostatic chuck is configured to have the plurality of heat-transfer gas supply holes (the heat-transfer gas supply holes 230 or 230a) formed on the substrate support surface, the annular seal band (the seal band 212 or 212a) formed on the substrate support surface on the outer periphery side of the heat-transfer gas supply holes so as to surround the heat-transfer gas supply holes, and at least one first protrusion (the protrusion 210 or 210d) formed on the substrate support surface between the first heat-transfer gas supply hole closest to the seal band among the heat-transfer gas supply holes and the seal band. As a result, it is possible to suppress the temperature difference on the substrate W in the vicinity of the first heat-transfer gas supply hole.

According to each embodiment, the first protrusion is formed within the predetermined range centered on the first heat-transfer gas supply hole. As a result, it is possible to suppress the temperature difference on the substrate W in the vicinity of the first heat-transfer gas supply hole.

According to each embodiment, the first heat-transfer gas supply hole includes the plurality of first heat-transfer gas supply holes formed on the substrate support surface in a point symmetrical relationship with the center of the substrate support surface. The first protrusion includes the plurality of first protrusions formed within the predetermined range centered on each of the first heat-transfer gas supply holes. As a result, in the plane of the substrate W, it is possible to suppress the temperature difference on the substrate W in the vicinity of each of the first heat-transfer gas supply holes.

According to each embodiment, the electrostatic chuck is configured to further have the plurality of second protrusions (the protrusions 211) formed on the substrate support surface on the second circumference (the circumference 211a to 211e) that is concentric with the first circumference (the groove 220 or 220a) on which the first heat-transfer gas supply holes are formed. The first protrusions are formed within the range between the extension lines obtained by extending the lines that connect two second protrusions located ahead and behind the first heat-transfer gas supply hole on the second circumference (circumference 211d or 211e) closest to the first circumference and the center of the substrate support surface toward the seal band. As a result, it is possible to suppress the temperature difference in the plane of the substrate W while supporting the substrate W.

According to each embodiment, the heat-transfer gas supply holes have porous members 234 through which the heat-transfer gas is capable of passing. As a result, it is possible to suppress abnormal discharge inside the heat-transfer gas supply holes.

According to each embodiment, the heat-transfer gas supply holes are formed at the bottom of the groove (the groove 220 or 220a) formed in a circumferential direction of the substrate support surface. As a result, it is possible to further diffuse the heat-transfer gas in the circumferential direction.

According to the present disclosure in some embodiments, it is possible to suppress a temperature difference on a substrate near a heat-transfer gas supply holes.

The embodiments disclosed herein should be considered to be exemplary and not limitative in all respects. The above-described embodiments may be omitted, substituted, or modified in various forms without departing from the scope and spirit of the appended claims.

Further, the present disclosure may have the following configurations.
(1) A substrate processing apparatus includes a plasma processing chamber, a base arranged inside the plasma processing chamber, and an electrostatic chuck arranged on the base and having a substrate support surface and a ring support surface. The electrostatic chuck is configured to include a plurality of heat-transfer gas supply holes formed in the substrate support surface, an annular seal band formed on the substrate support surface around an outer periphery of the plurality of heat-transfer gas supply holes so as to surround the plurality of heat-transfer gas supply holes, and at least one first protrusion formed on the substrate support surface between a first heat-transfer gas supply hole closest to the seal band among the plurality of heat-transfer gas supply holes and the seal band.
(2) In the substrate processing apparatus of (1) above, the at least one first protrusion is formed within a predetermined range centered on the first heat-transfer gas supply hole.
(3) In the substrate processing apparatus of (2) above, the first heat-transfer gas supply hole includes a plurality of first heat-transfer gas supply holes formed in the substrate support surface in a point symmetrical relationship with a center of the substrate support surface, and the at least one first protrusion includes a plurality of first protrusions formed within the predetermined range centered on each of the plurality of first heat-transfer gas supply holes.
(4) In the substrate processing apparatus of (3) above, the electrostatic chuck is configured to further include a plurality of second protrusions formed on the substrate support surface on a second circumference that is concentric with a first circumference on which the plurality of first heat-transfer gas supply holes are formed, and the plurality of first protrusions are formed within a range between extension lines obtained by extending lines that connect two second protrusions located ahead and behind the first heat-transfer gas supply hole in a circumferential direction on the second circumference closest to the first circumference and the center of the substrate support surface toward the seal band.
(5) In the substrate processing apparatus of any one of (1) to (4) above, the plurality of heat-transfer gas supply holes have porous members through which a heat-transfer gas is capable of passing.
(6) In the substrate processing apparatus of any one of (1) to (5) above, the plurality of heat-transfer gas supply holes are formed at a bottom of a groove formed in the substrate support surface in a circumferential direction of the substrate support surface.
(7) An electrostatic chuck arranged on a base arranged inside a plasma processing chamber and having a substrate support surface and a ring support surface, includes a plurality of heat-transfer gas supply holes formed in the substrate support surface, an annular seal band formed on the substrate support surface around an outer periphery of the plurality of heat-transfer gas supply holes so as to surround the plurality of heat-transfer gas supply holes, and at least one first protrusion formed on the substrate support surface between a first heat-transfer gas supply hole closest to the seal band among the plurality of heat-transfer gas supply holes and the seal band.
(8) In the electrostatic chuck of (7) above, the at least one first protrusion is formed within a predetermined range centered on the first heat-transfer gas supply hole.
(9) In the electrostatic chuck of (8) above, the first heat-transfer gas supply hole includes a plurality of first heat-transfer gas supply holes formed in the substrate support surface in a point symmetrical relationship with a center of the substrate support surface, and the at least one first protrusion includes a plurality of first protrusions formed within the predetermined range centered on each of the plurality of first heat-transfer gas supply holes.
(10) The electrostatic chuck of (9) above further includes a plurality of second protrusions formed on the substrate support surface on a second circumference that is concentric with a first circumference on which the plurality of first heat-transfer gas supply holes are formed. The plurality of first protrusions are formed within a range between extension lines obtained by extending lines that connect two second protrusions located ahead and behind the first heat-transfer gas supply hole in a circumferential direction on the second circumference closest to the first circumference and the center of the substrate support surface toward the seal band.
(11) In the electrostatic chuck of any one of (7) to (10), the plurality of heat-transfer gas supply holes have porous members through which a heat-transfer gas is capable of passing.
(12) In the electrostatic chuck of (7) to (11) above, the plurality of heat-transfer gas supply holes are formed at a bottom of a groove formed in the substrate support surface in a circumferential direction of the substrate support surface.

What is claimed is:

1. A substrate processing apparatus, comprising:
a plasma processing chamber;
a base arranged inside the plasma processing chamber; and
an electrostatic chuck arranged on the base and having a substrate support surface and a ring support surface,
wherein the electrostatic chuck is configured to include a plurality of heat-transfer gas supply holes formed on the substrate support surface, an annular seal band formed on the substrate support surface around an outer periphery of the plurality of heat-transfer gas supply holes so as to surround the plurality of heat-transfer gas supply holes, and at least one first protrusion formed on the substrate support surface between a first heat-transfer gas supply hole closest to the seal band among the plurality of heat-transfer gas supply holes and the seal band.

2. The substrate processing apparatus of claim 1, wherein the at least one first protrusion is formed within a predetermined range centered on the first heat-transfer gas supply hole.

3. The substrate processing apparatus of claim 2, wherein the first heat-transfer gas supply hole includes a plurality of first heat-transfer gas supply holes formed on the substrate support surface in a point symmetrical relationship with a center of the substrate support surface, and
wherein the at least one first protrusion includes a plurality of first protrusions formed within the predetermined range centered on each of the plurality of first heat-transfer gas supply holes.

4. The substrate processing apparatus of claim 3, wherein the electrostatic chuck is configured to further include a plurality of second protrusions formed on the substrate support surface on a second circumference that is concentric with a first circumference on which the plurality of first heat-transfer gas supply holes are formed, and
wherein the plurality of first protrusions are formed within a range between extension lines obtained by extending lines that connect two second protrusions located ahead and behind the first heat-transfer gas supply hole in a circumferential direction on the second circumference closest to the first circumference and the center of the substrate support surface toward the seal band.

5. The substrate processing apparatus of claim 1, wherein the plurality of heat-transfer gas supply holes have porous members through which a heat-transfer gas is capable of passing.

6. The substrate processing apparatus of claim 1, wherein the plurality of heat-transfer gas supply holes are formed at a bottom of a groove formed in the substrate support surface in a circumferential direction of the substrate support surface.

7. An electrostatic chuck arranged on a base arranged inside a plasma processing chamber, the electrostatic chuck comprising:
a substrate support surface and a ring support surface
a plurality of heat-transfer gas supply holes formed on the substrate support surface;
an annular seal band formed on the substrate support surface around an outer periphery of the plurality of heat-transfer gas supply holes so as to surround the plurality of heat-transfer gas supply holes; and
at least one first protrusion formed on the substrate support surface between a first heat-transfer gas supply hole closest to the seal band among the plurality of heat-transfer gas supply holes and the seal band.

8. The electrostatic chuck of claim 7, wherein the at least one first protrusion is formed within a predetermined range centered on the first heat-transfer gas supply hole.

9. The electrostatic chuck of claim 8, wherein the first heat-transfer gas supply hole includes a plurality of first heat-transfer gas supply holes formed on the substrate support surface in a point symmetrical relationship with a center of the substrate support surface, and
wherein the at least one first protrusion includes a plurality of first protrusions formed within the predetermined range centered on each of the plurality of first heat-transfer gas supply holes.

10. The electrostatic chuck of claim 9, further comprising:
a plurality of second protrusions formed on the substrate support surface on a second circumference that is concentric with a first circumference on which the plurality of first heat-transfer gas supply holes are formed,
wherein the plurality of first protrusions are formed within a range between extension lines obtained by extending lines that connect two second protrusions located ahead and behind the first heat-transfer gas supply hole in a circumferential direction on the second circumference closest to the first circumference and the center of the substrate support surface toward the seal band.

11. The electrostatic chuck of claim 7, wherein the plurality of heat-transfer gas supply holes have porous members through which a heat-transfer gas is capable of passing.

12. The electrostatic chuck of claim 7, wherein the plurality of heat-transfer gas supply holes are formed at a bottom of a groove formed on the substrate support surface in a circumferential direction of the substrate support surface.
